(19) United States
(12) Patent Application Publication
(10) Pub. No.: US 2026/0333612 A1
(43) Pub. Date: Oct. 22, 2026

(54) Pivotable Electronics Housing, Pivoting Device, Pivotable Electronics Device, Housing Assembly and Climate Control Unit

(71) Applicant: Viessmann Holding International GmbH, Allendorf (DE)

(72) Inventor: FEUSSNER Yannick, Burgwald (DE)

(21) Appl. No.: 19/566,891

(22) Filed: Mar. 13, 2026

(30) Foreign Application Priority Data
Mar. 14, 2024 (DE) 10 2025 109 850.6

(51) Int. Cl. H05K 7/16; H05K 7/14

(52) U.S. Cl. CPC H05K 7/16; H05K 7/1427

(57) ABSTRACT

The invention provides an electronics housing 100 for accommodating electrical circuit boards 400, which electronics housing comprises a housing 101 with an accommodation space 102 and a cable-guiding pivoting device 200 for fastening to a carrier body, which pivoting device permits a pivoting movement of the housing 101 when the electronics housing 100 is fastened to the carrier body, wherein the cable-guiding pivoting device 200 is designed to guide a portion of a cable 401 which runs from a surrounding area of the housing 101 into the accommodation space 102 and, for this purpose, comprises a cable fastening portion 201. The cable fastening portion 201 comprises a concave bearing surface 202, on which the portion of the cable 401 can rest, and a holding section 203 which is located below the bearing surface 202 and on which a fastening means 204 can engage in order to fasten the portion of the cable 401, which rests on the bearing surface 202, to the pivoting device 200.

### TECHNICAL FIELD

The present invention relates to a pivotable electronics housing, a pivoting device, a pivotable electronics device, a housing assembly for a climate control unit and a climate control unit.

### BACKGROUND OF THE INVENTION

In recent times, climate control systems are increasingly used, especially in private households, by means of which room climate control and/or a supply with temperature-controlled service water is implemented.

An example of such a climate control system is a heat pump system or an air conditioning system, which are thermodynamic systems, by means of which various ambient energy sources, for example by means of aerothermia, geothermia or hydrothermia, can be made usable for room climate control and/or for temperature control of service water.

For this purpose, the climate control system is used as a type of interface in order to bring about an energy or heat flow between said ambient energy source and one or more target system(s), which may be, for example, a heating, ventilation or service water circuit.

Depending on the direction of the heat flow, thermal energy (thermal energy) can thus be supplied to or withdrawn from the target system, for example in order to either increase or lower a temperature of an energy transport medium of a heating circuit, in order thus ultimately to be able to heat or cool rooms.

In particular in the case of a heat pump system, the latter usually comprises one or more interconnected units, so-called heat pump units, wherein at least one of these units usually comprises a closed thermodynamic working circuit (often also referred to as a refrigeration circuit or refrigerant circuit) for a working medium (often also referred to as a refrigerant) or at least a part of such a circuit. In the refrigeration circuit, during operation of the heat pump system, thermal energy is transferred via a heat exchanger to the refrigerant at a first point and, at at least one further point in the refrigeration circuit, thermal energy is withdrawn from the refrigerant via a further heat exchanger, in order thus to convert a heat flow into or out of the target system. The technical backgrounds in this respect are sufficiently well known.

In the case of an embodiment with only one unit, this may be, for example, an internally installed heat pump unit with an integrated refrigeration circuit.

A plurality of units may be, for example, an embodiment with an indoor unit and an outdoor unit. In this case, the refrigeration circuit may be embodied as part of the indoor unit or as part of the outdoor unit. Likewise, the refrigeration circuit may also be split according to a split principle, such that both the indoor unit and the outdoor unit each comprise a part of the refrigeration circuit.

In this case, one unit is usually designed for an installation location located within a building and is generally connected to an outdoor unit, if this is present. In this case, the outdoor unit may function as a heat source unit, via which thermal energy can be obtained from an ambient energy source or can be output to the latter.

Similar embodiments are also found in air conditioning systems, which are usually used for cooling a ventilation flow and may likewise be composed, for example, of an indoor unit and an outdoor unit.

Since, in particular, end users expect a high degree of comfort and control options, diverse control possibilities are moreover provided by the user. By way of example, an app control and the integration into a smart home system are mentioned here. These functions must all be supported by appropriate control electronics, irrespective of their specific form.

Therefore, various electrical units, such as printed circuit boards, integrated circuits and/or circuits, which contain various electrical components, are regularly found in a housing of a climate control unit. In particular, it is usual in this case to accommodate electrical assemblies in a housing, which expediently differ in terms of their voltage.

Thus, both power electronic assemblies and assemblies for control are usually used. In particular, assemblies with a different voltage, for example assemblies with a voltage of 400 V or 230 V and assemblies with a lower voltage, such as 12 V or 24 V, can also be accommodated in the same housing.

In order to guarantee safe operation in these cases, it is usual to consider and optimize the electromagnetic compatibility (EMC) of the assemblies and elements used.

In particular, the positioning of assemblies, such as populated electrical circuit boards, with respect to one another, and also the positioning of electrical circuit boards, which are used for control purposes, with respect to power electronic components or motors, plays an important role in this case.

In this case, however, it should be noted that the available space is limited, and corresponding assemblies and elements cannot be removed arbitrarily far from one another.

In order to achieve good EMC despite the restricted installation space in the interior of a housing, control boxes in which electrical circuit boards can be mounted are usually used.

Since the installation space within housings is often utilized to a high degree, the installation of these control boxes is difficult, however, and access for maintenance or the like is often cumbersome.

### SUMMARY

It is an object of the present invention to provide an improved mounting concept for electronic assemblies, in particular electrical circuit boards with connected cables, which enables efficient mounting and maintenance at high EMC.

In order to achieve this object, the pivotable electronics housing according to claim 1, the pivoting device according to claim 12, the pivotable electronics device according to claim 13, the housing assembly according to claim 14 and the climate control unit according to claim 15 are provided.

In this case, the respective dependent claims relate to preferred embodiments which can each be provided on their own or in combination.

According to a first aspect, a pivotable electronics housing for accommodating electrical circuit boards is provided. In this case, the electronics housing comprises a housing which surrounds an accommodation space in which at least one electrical circuit board can be accommodated; and at least one pivoting device for fastening the housing to a carrier body. In this case, the pivoting device, in a state in which it is fastened to the carrier body, permits at least one pivoting movement of the housing relative to the carrier body. The pivoting device is a cable-guiding pivoting device which is designed to guide a portion of a cable which runs from a surrounding area of the housing into the accommodation space. The cable-guiding pivoting device comprises at least one cable fastening portion which has a concave bearing surface, on which the guided portion of the cable can rest. Furthermore, the cable fastening portion has a holding section which is located below the bearing surface and on which a fastening means can engage in order to fasten the portion of the cable, which rests on the bearing surface, to the pivoting device.

As a result, an electronics housing is provided which enables efficient and flexible mounting of electrical circuit boards. In this case, the cable-guiding pivoting device enables flexible and simple mounting of the electronics housing and at the same time facilitates maintenance.

In this case, the housing of the electronics housing is not further limited and can be designed in particular as a plastic housing or metal housing, in particular with an insulation layer.

Furthermore, the accommodation space of the housing is not to be understood as being further limited.

Any body to which the electronics housing can be fastened is to be understood as a carrier body. By way of example and not exhaustively, this may be an accommodation frame, a housing, also a special region of a housing or a wall.

Preferably, the pivoting device is a hinge device.

Advantageously, the accommodation space for accommodating at least one electrical circuit board additionally comprises at least one suitable accommodation device. In particular, the accommodation device may be supports to which a circuit board to be accommodated is fastened. Furthermore, the electrical circuit board may also be accommodated in the accommodation space, for example, by a corresponding plug-in or clamping connection.

As a result, an electrical circuit board can be accommodated in the accommodation space particularly simply and quickly, in particular without the need for a tool insert.

Advantageously, the housing does not completely surround the accommodation space. For example, the housing may also have cutouts, holes or slots, in particular for ventilation purposes. These may be arranged in accordance with a position of the electrical circuit board in the accommodation space.

This embodiment allows better cooling of the accommodated electrical circuit board and/or of electrical components which are mounted thereon.

Advantageously, the at least one pivoting device of the electronics housing comprises at least two separate pivoting elements. In particular, these are not fixed to a specific embodiment.

This embodiment permits easier mounting since the alignment of a large pivoting device during mounting is dispensed with.

The cable fastening portion with the concave bearing surface is advantageously formed integrally with the pivoting device.

As a result, mounting is further facilitated since additional components can be dispensed with. In addition, a higher stability of the cable fastening portion is achieved in this embodiment.

The concave shape of the bearing surface permits cables of different diameters to be fastened to the cable fastening portion without cables of larger diameter being squeezed too much or cables of smaller diameter being fastened inadequately.

In another advantageous embodiment, the cable fastening portion is produced as a further component which is connected to the pivoting device.

In this way, easier fastening of cables can be achieved depending on the access to the pivoting device. If access is made more difficult, for example, a cable can already be connected to the cable fastening portion before final mounting before said cable fastening portion is fastened to the pivoting device in a second step.

For this purpose, the pivoting device and the cable fastening portion may advantageously have a connecting portion for producing a form-fitting connection, in particular a plug connection.

In an advantageous embodiment of the electronics housing, the holding section which is located below the bearing surface is embodied as a groove-shaped formation integrally with the pivoting device.

In particular, when the pivoting device is connected to the carrier body, the groove-shaped formation forms a leadthrough with a surface of said carrier body.

In other words, when the pivoting device is connected to the carrier body, said pivoting device lies on said carrier body in such a way that a leadthrough, in particular for a fastening means, is formed, the circumference of which leadthrough is delimited on one side by a surface of the carrier body and is delimited on the other sides by the groove-shaped formation of the pivoting device.

As a result, in particular maintenance work is facilitated since fastening means can be attached or removed without the pivoting device and/or the electronics housing having to be dismounted overall. Cables can therefore be fastened to the cable fastening portion or removed therefrom only by the addition or removal of fastening means. Therefore, for example, a cable exchange is substantially accelerated without dispensing with the safety of a cable fastening.

In a further advantageous embodiment, the holding section has at least one thread.

In this way, a fastening means, such as, for example, a clamp, can fix cables on the bearing surface and therefore fasten them to the cable fastening portion by means of a screw which engages in the thread of the holding section.

Fastening means is not to be understood as being further limited. In particular, fastening means such as (rubber or Velcro) tapes, clamps, adhesives, clamps, clamps or cable ties can be used in order to fasten cables to the cable fastening portion.

The cable fastening portion permits a portion of a cable to be guided from a surrounding area of the housing into the accommodation space.

Advantageously, the cable fastening portion is configured to provide strain relief for cables fastened to it.

For this purpose, the cable fastening portion is dimensioned correspondingly large, for example, and/or has a geometry which permits tensile forces to be absorbed.

The cable fastening portion on the pivoting device enables the electronics housing to be used in a particularly flexible manner. Thus, for example, corresponding excess lengths can be provided during the fastening of cables, which excess lengths are then available when the electronics housing is pivoted. In this way, it is avoided that cable connections become detached during the pivoting of the electronics housing or are even damaged by the pivoting operation.

The electronics housing can therefore advantageously also be mounted in positions which, although desired on the one hand, for example on account of EMC and/or for the local separation of mains voltage and low voltage, are undesirable on the other hand, for example on account of accessibility into an interior of the carrier body, since the electronics housing can also be pivoted very frequently by the cable fastening portion without having to fear an interruption in the connection of fastened cables.

Furthermore, the cable fastening portion permits different cables to be guided in different directions in the surrounding area of the electronics housing.

As a result, the electronics housing can be used particularly advantageously for complex use scenarios which, in addition to the electronics housing with the accommodated electrical circuit boards, have a plurality of other electrical assemblies. Different cables can already be guided in the required directions proceeding from the electronics housing by being fastened correspondingly to the cable fastening portion.

The electronics housing, including the electrical circuit boards with connected cables accommodated therein, can thus advantageously be considered, prepared and mounted as a single unit, as a result of which it can be used particularly efficiently.

In a preferred embodiment, the pivoting device comprises an attachment interface section which is adapted to a receiving section of the carrier body in such a way that the pivoting device is fastened to the carrier body in a form-fitting and/or force-fitting manner when the attachment interface section and the receiving section are brought into interaction.

In this way, the electronics housing can be mounted even more efficiently since the attachment interface section and the receiving section can be brought into interaction on the carrier body, in particular without tools.

In an advantageous embodiment, the attachment interface section and the receiving section can be released from one another in a non-destructive manner on the carrier body, which facilitates, for example, an exchange of parts of the electronics housing.

In particular, maintenance of electrical circuit boards accommodated in the electronics housing is facilitated as a result since the electronics housing as a whole can be removed from the carrier body, as a result of which the maintenance can take place, for example, in a more favorable position, such as sitting on a table, instead of standing in front of the electronics housing.

In a further preferred embodiment, the attachment interface section and the receiving section are configured in such a way that they can be released from one another by elastic deformation of the attachment interface section and/or of the receiving section.

In a particularly preferred embodiment, the attachment interface section and the receiving section are designed as a latching mechanism in which an elastic latching or hook section engages in a latching or hook opening adapted thereto when the attachment interface section and the receiving section are brought into interaction.

For this purpose, the latching or hook section particularly advantageously comprises at least two elastic hooks and the carrier body correspondingly comprises at least two latching or hook openings in order to guarantee a safe connection of pivoting device and carrier body in this way.

In a preferred embodiment, the at least one cable fastening portion of the pivoting device has an alignment section for guiding and/or aligning the fastening means, which alignment section guides the fastening means during a movement of the fastening means relative to the holding section and/or aligns it with respect to the holding section when the fastening means is brought into interaction with the alignment section.

In a further preferred embodiment, the holding section is of groove-shaped design and the alignment section is preferably formed by an arc-shaped deflection section which is located at one end of the holding section and at which a fastening means which is guided through the holding section is deflected, preferably the ends of the deflection section are at an angle of 50° to 130° with respect to one another, particularly preferably at an angle of 70° to 100°.

The angle ranges mentioned are advantageously selected here with regard to the fastening means to be expected in order to make it more difficult for fastening means of different sizes to bend or break.

In particular in the case of cable ties, it is necessary here to consider the thickness with which they are embodied since the thickness of the cable ties to be inserted has a direct effect on a minimum angle of the ends of the deflection section with respect to one another. Even if damage to the cable ties is not to be expected, an angle which is selected to be too small can lead to more difficult handling until cable ties which are to be deflected remain stuck.

Advantageously, the alignment section aligns a fastening means which is guided through the groove-shaped holding section in a direction substantially parallel to the main direction of extension of the latter in such a way that the fastening means leaves the alignment section in a direction substantially perpendicular to the main direction of extension of the holding section. This in particular facilitates access to the aligned end of the fastening means and thus accelerates its use.

In a particularly advantageous embodiment, such an arc-shaped deflection section is located on both sides of the groove-shaped holding section. In this way, a fastening means can already be inserted in a direction substantially perpendicular to the main direction of extension of the holding section, wherein it is deflected by the first deflection section in such a way that it is guided through the groove-shaped holding section. As the fastening means is guided through further, its guided-through end is then deflected again by the second deflection section and therefore leaves the holding section substantially parallel to the inserted end. As a result, handling of the fastening means is further facilitated, which accelerates its use again and thus increases the efficiency.

Particularly advantageously, in this way, an at least partially flexible fastening means, in particular a cable tie, can be used in order to fasten cables to the cable fastening portion of the pivoting device. Particularly if the electronics housing has been installed in an inaccessible region, the fastening of cables by the alignment section is substantially facilitated.

In particular, the alignment section advantageously prevents, by virtue of its shape, the cable tie from remaining stuck or abutting.

In an advantageous embodiment, the alignment section is additionally configured to prevent a fastening element from being guided through completely.

For example, the alignment section is dimensioned in such a way that the head end of a cable tie cannot be guided through. In this way, the fastening of cables to the cable fastening portion of the pivoting device can be effected with one hand by means of a cable tie, which is advantageous particularly in the case of control boxes which are difficult to access and difficult to illuminate.

In a further preferred embodiment, the pivoting device is of multi-part design and comprises at least one carrier-body-side part and one housing-side part which can be pivoted with respect to one another and which are releasably connected to one another via a connecting means, wherein preferably the carrier-body-side part has the at least one cable fastening portion.

The (de)mounting of the electronics housing of this embodiment is particularly efficient. Thus, the housing of the electronics housing as a whole can be removed from the carrier body or connected to the latter without the pivoting device itself having to be removed from the carrier body or connected to the latter.

This permits, for example, simple replacement of the electrical circuit boards which are mounted in the electronics housing without cables fastened to the pivoting device having to be released. All cables only have to be separated from the electrical circuit boards in the electronics housing. Subsequently, the connecting means can be removed and the electronics housing, including all circuit boards accommodated therein, can be removed.

In this case, all means which enable releasable connection of the housing to the pivoting device are to be understood as connecting means. By way of example and not exhaustively, the connecting means may be screws or bolts.

This embodiment additionally permits cables provided to be able to be mounted on the cable fastening portion of a pivoting device which is already mounted independently of the electronics housing, which particularly increases the mounting efficiency.

Furthermore, cables may also already be fastened such that they are equipped and aligned with mounting length in accordance with a later connection position. This procedure avoids mounting errors as a result of incorrect cable connections and therefore again increases the efficiency and safety.

In a further preferred embodiment, the pivoting device additionally comprises a positioning aid by means of which the pivoting device can be positioned in a connecting position on and/or in the carrier body.

Any optical and/or haptic means which permit the pivoting device to be positioned in a connecting position on and/or in the carrier body are to be understood as a positioning aid. In particular and not exhaustively, a positioning aid may be cutouts in the pivoting device, printed-on or introduced markings of the pivoting device or formations of the pivoting device which make contact with surfaces, edges and/or formations of the carrier body and/or engage into said surfaces, edges and/or formations.

The positioning aid of the pivoting device is advantageously formed as a set of formations which engage into corresponding cutouts of the carrier body in the connecting position. In this way, the pivoting device can be brought into the connecting position quickly and in a controllable manner, as a result of which a mounting efficiency of the pivoting device is increased.

In an additional preferred embodiment, the pivoting device comprises one or more further cable fastening portions which each have a concave bearing surface, on which the portion of the cable can rest, and a holding section which is located below the bearing surface and on which a fastening means can engage in order to fasten the portion of the cable, which rests on the bearing surface, to the pivoting device.

The additional possibilities which are thereby opened up for fastening cables to the pivoting device further increase the flexibility of how cables can be guided out of or into the electronics housing.

In a further preferred embodiment, the at least one cable fastening portion and the one or more further cable fastening portions are arranged symmetrically.

The pivoting device is particularly advantageously formed symmetrically overall.

In this way, the pivoting device can be connected to the carrier body in a very versatile manner. In particular, a connection is thus enabled for example on two mutually opposite sides of an engagement region in the carrier body.

Particularly advantageously, flexible conversions are also made possible by this embodiment. For example, depending on the circumstances of a space in which the carrier body is installed, the electronics housing can be connected to the latter. If, for example, it is not possible in the installation space for the electronics housing to be able to be pivoted to a right-hand side relative to the carrier body, the pivoting device which is embodied in a mirror-symmetrical manner permits a connection in such a way that the electronics housing can be pivoted to a left-hand side relative to the carrier body, which increases the flexibility of use of the electronics housing.

In a further preferred embodiment, the electronics housing comprises one or more further pivoting devices.

Thus, switchgear cabinet housings with greatly differing sizes can also be used since the number and position of the pivoting devices relative to the housing of the switchgear cabinet can be easily changed.

Furthermore advantageously, the organization of the cables fastened to the pivoting devices can be further improved. For example, cables which are guided into the housing of the electronics housing can be fastened to one or to the other pivoting device depending on the voltage which they guide. A separation according to signal type and/or according to voltage is also advantageous.

According to a further aspect of the invention, a pivoting device of an electronics housing is provided which is used as above in connection with the electronics housing.

In particular, the pivoting device is configured such that a pivoting body, for example the housing of the electronics housing, can be pivoted relative to a carrier body via it when the pivoting device is fastened to the pivoting body and to the carrier body. The pivoting device is a cable-guiding pivoting device which is designed to guide a portion of a cable which runs from a surrounding area on the carrier body side into a surrounding area on the pivoting body side. The cable-guiding pivoting device comprises at least one cable fastening portion which has a concave bearing surface, on which the portion of the cable can rest, and a holding section which is located below the bearing surface and on which a fastening means can engage in order to fasten the portion of the cable, which rests on the bearing surface, to the pivoting device.

According to a further aspect of the invention, a pivotable electronics device is provided which comprises an electronics housing as described above and at least one electrical circuit board which is accommodated in the accommodation space of the electronics housing and in particular is fastened there.

According to a further aspect of the invention, a housing assembly for use in a climate control unit is provided. In this case, the housing assembly comprises one or more housing elements which together define an interior space and an electronics housing as described above. In this case, the electronics housing, by way of its pivoting device, is fastened in a pivotable manner to one of the one or more housing elements which functions as a carrier body.

Preferably, the electronics housing is fastened in such a way that it is located completely or partially in the interior space at least in a first pivoting position.

In this way, the housing assembly can advantageously be dimensioned in a space-saving manner since the required electronics, in particular the electrical circuit boards, can be accommodated in the electronics housing in the interior space.

In other words, the housing assembly with the electronics housing has a dedicated location at which electrical circuit boards can be accommodated. Since the electronics housing can be positioned in a very flexible manner as described above, there is additionally the possibility of advantageously positioning the electrical circuit boards in the housing assembly with regard to EMC by virtue of the electronics housing being fastened in a fitting manner to a housing element by means of the pivoting device.

Furthermore advantageously, it is possible here to disregard aspects such as the accessibility of the interior space with regard to EMC-favorable positioning of the circuit boards since the electronics housing, on account of its pivotability, can be pivoted to a different position, for example a service position.

In an advantageous embodiment of the housing assembly, the electronics housing is in this case positioned in such a way that it can be pivoted at least into a maintenance position in which it projects out of the interior space.

As a result, the electronics housing does not block the access to the interior space if the latter is required. If the access is not required, the electronics housing can be pivoted back into the interior space. It is thus possible to ensure optimum use of the limited space in the interior space.

The pivoting device of the electronics housing in this case permits the position of the electronics housing to be changed and adapted to the specific use.

According to a further aspect of the invention, a climate control unit is provided which comprises a housing assembly as described above, at least one electrical circuit board which is accommodated in the accommodation space of the electronics housing, and at least one cable. The cable in this case is connected to the at least one circuit board, is guided out of the accommodation space by way of the cable-guiding pivoting device, rests on the bearing surface and is fastened to the pivoting device by means of a fastening means which engages on the holding section.

As a result, efficient mounting of the different assemblies of the climate control unit is made possible. Thus, in particular, the cabling can be carried out in a very flexible manner since the cables can already be fastened to the pivoting device at an early stage, to be precise irrespective of the mounting sequence of the components to be connected to the cables. Since, furthermore, required lengths can also be prepared in advance, cabling errors are also reduced, which increases the safety of the climate control unit.

In an advantageous embodiment, the climate control unit comprises two electrical circuit boards which are accommodated in the accommodation space of the electronics housing and at least two cables, wherein one of the cables is connected to each of the electrical circuit boards, each of the cables is guided out of the accommodation space by way of the cable-guiding pivoting device, rests on the bearing surface and is fastened to the pivoting device by means of a fastening means which engages on the holding section, in such a way that at least two of the cables are guided in different directions in the interior space.

This results in the possibility of laying cabling for different purposes already at an early stage separately from one another in the housing assembly. In particular, cables of different voltage levels or for different control purposes can be guided separately from one another in the housing and can already be fastened to the pivoting device running in different directions in such a way that the risk of incorrect cabling on the electrical circuit boards in the electronics housing is minimized. As a result, the mounting efficiency and safety are further increased both during the mounting and during the operation of the climate control unit.

In a preferred embodiment, the climate control unit further comprises one or more hydraulic components of a hydraulic circuit which are arranged partially or completely in the interior space, and/or a refrigerant circuit which is arranged partially or completely in the interior space, and/or parts of a refrigerant circuit which is arranged partially or completely in the interior space.

The hydraulic circuit can be, for example, a hydraulic circuit for transporting an energy transport medium which is temperature-controlled by the climate control system, for example by means of a temperature control device which comprises, in particular, a refrigerant circuit, in particular a heating circuit for heating rooms and/or for heating service water.

The temperature control device may be, for example, an outdoor unit of the climate control system.

The temperature-controlled energy transport medium can then be used, for example, for climate control of a room in which it is conducted to a heat exchanger in said room, and/or for heating service water in which it is conducted to a heat exchanger of a service water system.

In this case, hydraulic components of the hydraulic circuit which are embodied as part of the climate control unit may be one or more from the following group:
a circulating pump for conveying the energy transport medium;
a pressure accumulator;
control and/or regulating valves.

The climate control unit preferably comprises connections for connecting the hydraulic components to the hydraulic circuit. These connections preferably comprise one or more of the following connections:
a heating circuit feed connection which can be connected to a feed of a heating circuit,
a heating circuit return connection which can be connected to a return of a heating circuit;
a service water system feed connection which can be connected to a feed of a service water system;
a service water system return connection which can be connected to a return of a service water system;
a first temperature control device connection which can be connected to a return of the temperature control device in order to supply it with energy transport medium which is to be temperature-controlled;
a second temperature control device connection which can be connected to a feed of the temperature control device in order to obtain energy transport medium which is temperature-controlled by the temperature control device.

Preferably, in this case, the hydraulic components of the climate control unit are connected to one another in such a way that the energy transport medium flowing into the heating circuit return connection and/or into the service water system return connection can be conducted via the first temperature control device connection to a temperature control device in which the energy transport medium can be temperature-controlled. Preferably, the hydraulic components of the climate control unit are furthermore connected to one another in such a way that the energy transport medium flowing into the second temperature control device connection can be supplied via the heating circuit feed connection to a heating circuit and/or via the service water system return connection to a service water system.

Preferably, the refrigerant circuit comprises, in the case of such a customary component, namely a first heat exchanger and a second heat exchanger, via which thermal energy can in each case be supplied to and/or withdrawn from the refrigerant, a compression device for compressing the refrigerant, and an expansion device for expanding the refrigerant.

Further aspects and the advantages thereof and also more specific exemplary embodiments of the abovementioned aspects and embodiments are described below with the aid of the drawings which are shown in the appended figures.

FIG. 1 shows a sectional view of an advantageous exemplary embodiment of the electronics housing with a connected pivoting device, wherein two electrical circuit boards are accommodated in the accommodation space.

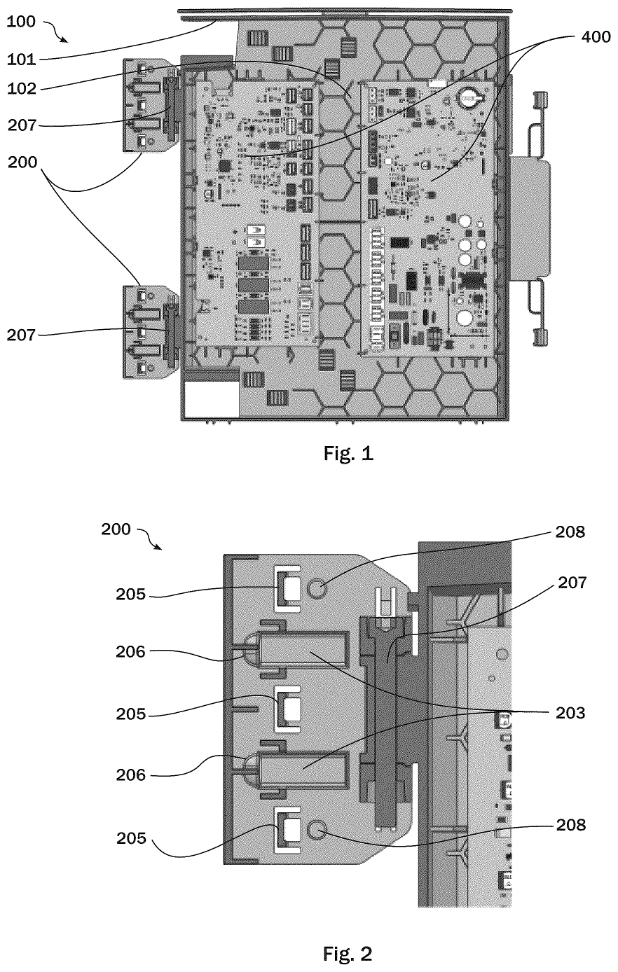

FIG. 2 shows a sectional view of part of an exemplary embodiment of the pivoting device of the electronics housing from FIG. 1.

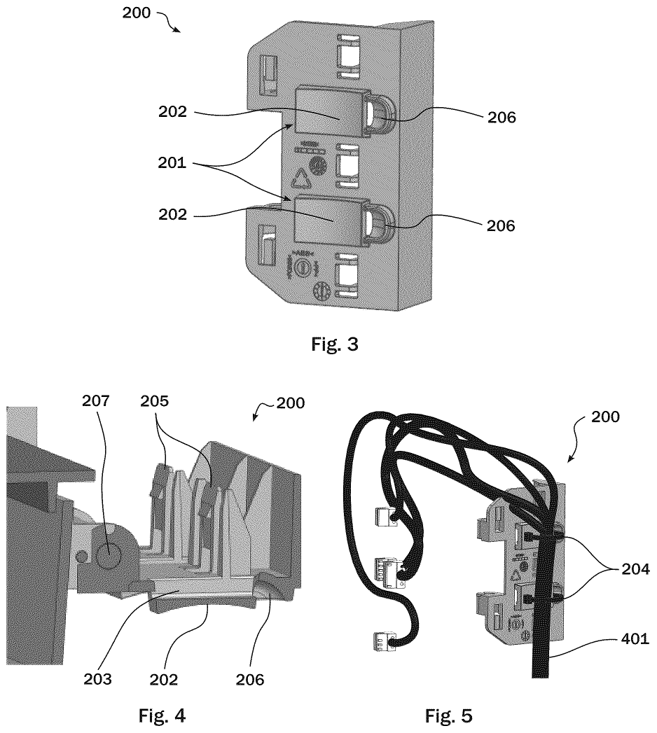

FIG. 3 shows a view of the outer side of part of an advantageous exemplary embodiment of the pivoting device.

FIG. 4 shows a cross section of an advantageous exemplary embodiment of the pivoting device of the electronics housing.

FIG. 5 shows an advantageous exemplary embodiment of the pivoting device with cables fastened thereto.

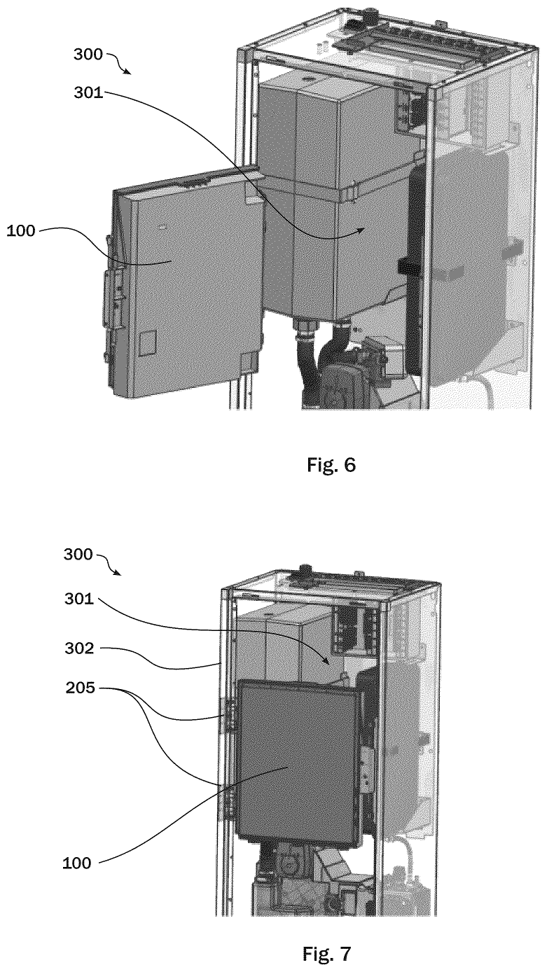

FIG. 6 shows an advantageous exemplary embodiment of a housing assembly with an electronics housing which is pivoted into a service position.

FIG. 7 shows an advantageous embodiment of a housing assembly with an electronics housing which is pivoted into an operating position.

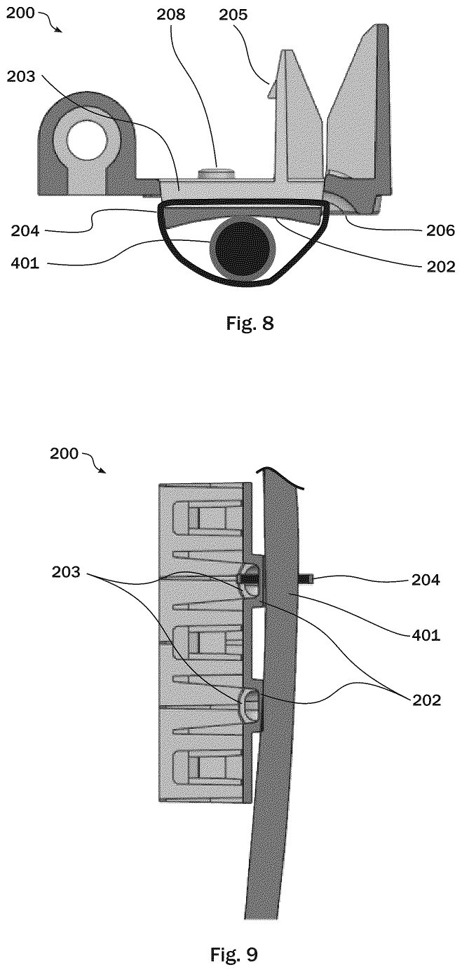

FIG. 8 shows a cross section of an advantageous exemplary embodiment of the pivoting device with cables fastened thereto, perpendicular to a main direction of extension of the cable.

FIG. 9 shows a cross section of an advantageous exemplary embodiment of the pivoting device with cables fastened thereto, parallel to a main direction of extension of the cable.

It is emphasized that the present invention is in no way limited to the exemplary embodiments described below and the exemplary features thereof. The invention furthermore comprises modifications of the exemplary embodiments mentioned, in particular those which emerge from modifications and/or combinations of individual or a plurality of features of the exemplary embodiments described within the scope of the independent claims.

### DETAILED DESCRIPTION OF THE FIGURES

FIG. 1 shows a sectional view of the electronics housing 100 with a connected pivoting device 200, wherein two electrical circuit boards 400 are accommodated in the accommodation space 102 of the housing 101 of the electronics housing.

The electronics housing 100 comprises a housing 101 with an accommodation space 102 in which two electrical circuit boards 400 are accommodated. Furthermore, the electronics housing 100 comprises a pivoting device 200 or, by way of example, two pivoting devices 200 which are each connected to the housing 101 by a connecting means 207.

In the exemplary embodiment from FIG. 1, the connecting means 207 is a bolt which in each case penetrates corresponding bores or holes in the housing 101 and the pivoting device 200, or the individual elements of the pivoting device 200, which is in particular a hinge device.

In this way, the housing 101 of the electronics housing 100 can be connected to the pivoting device 200 in a particularly simple and releasable manner, which enables simple insertion and removal of the housing 101 of the electronics housing 100, as a result of which mounting is particularly facilitated.

Advantageously, the bolt may be provided completely or partially with a thread which engages into a part of the pivoting device 200 in order to guarantee a safe connection of housing 101 and pivoting device 200.

The accommodation of the electrical circuit boards 400 is not particularly limited. In particular, these can be plugged, screwed, clamped or adhesively bonded into the accommodation space 102. The specific type of accommodation can be selected in accordance with the intended use and/or the circumstances of the use environment.

Preferably, the housing 101 of the electronics housing 100 is shaped in such a way that ingress of dripping water is prevented.

The specific type of shaping is not further limited in this case. In the exemplary embodiment from FIG. 1, the shaping comprises a radius of curvature of the upper side of the housing 101, such that dripping water can flow away laterally. Further advantages of the electronics housing 100 and in particular of the pivoting device 200 of the electronics housing 100 are explained with reference to FIG. 2.

FIG. 2 shows a sectional view of part of the pivoting device 200 of the electronics housing 100 from FIG. 1.

In particular, FIG. 2 illustrates a rear surface of the pivoting device which faces a housing element 302 (not visible in FIG. 2), when the pivoting device is connected to a carrier body.

Therefore, the rear-side holding sections 203 of the pivoting device 200, on which the fastening means 204 (not shown) engages for the purpose of fastening cables 401 to the cable fastening portion 201, can be seen centrally.

In the exemplary embodiment shown, these holding sections 203 are embodied as grooves in the material of the pivoting device 200. The open surface which can be seen in FIG. 2 is covered by the latter when the pivoting device 200 is connected to a carrier body, for example a housing element 302 of a housing assembly 300. A passage, through which the fastening means 204 can be guided, is therefore formed.

The alignment sections 206, which permit easy mounting of the fastening means 204, are located in each case at one end of the holding sections 203. For a more detailed description of the holding sections 203 and of the alignment sections 206, reference is made to the description relating to FIG. 4.

Furthermore, the positioning aid 208 is illustrated in the view in FIG. 2. In the exemplary embodiment shown, the positioning aid 208 is formed by two cylindrical shapes formed on the rear side of the pivoting device 200.

Said cylindrical shapes, in a connecting position, engage into corresponding cutouts on the carrier body, for example on the housing element 302.

In this way, the connection of the pivoting device 200 to the carrier body is facilitated and incorrect positioning is avoided. The positioning aid 208 is particularly advantageously formed such that it cannot engage in a fitting manner during a rotation and/or tilting of the pivoting device 200 in order to avoid a connection of the pivoting device 200 to the carrier body in such an undesired position.

Since the engagement of the positioning aid 208 in the carrier body results in a noticeable change in position of the pivoting device 200, the latter can be connected to the carrier body in particular easily at positions without direct visual contact (blind). As a result, mounting of the electronics housing 100 is further facilitated.

This type of mounting is further facilitated if the attachment interface section 205 and the corresponding receiving section on the housing element which forms the carrier body are formed to be secured against rotation.

FIG. 3 shows a view of the outer side of part of an advantageous exemplary embodiment of the pivoting device 200.

That side of the pivoting device 200 which is shown in FIG. 3 lies on the outside (i.e. is visible) when the pivoting device 200 is connected to the carrier body, for example a housing element 302 of a housing assembly 300.

The exemplary embodiment shown in FIG. 3 comprises cable fastening portions 201 which can be seen centrally. By means of these, cables 401, or portions of cables 401, can be fastened to the pivoting device 200.

In this case, the cable fastening portions 201 each comprise a concave bearing surface 202, a rear-side holding section 203 (not illustrated in FIG. 3) and an alignment section 206 for a fastening means 204.

In this case, the advantageous embodiment with two cable fastening portions 201 further increases the flexibility of use since there are more freedoms in the cable routing. Thus, on the one hand, more components can be cabled and, on the other hand, more complicated cabling concepts can also be realized since different cables 401 can also be guided in different directions by means of fastening to different cable fastening portions 201.

FIG. 4 shows a cross section of an advantageous exemplary embodiment of the pivoting device 200 perpendicular to a main direction of extension of the pivoting device 200.

The illustration in FIG. 4 shows in more detail the attachment interface section 205, which is designed as an elastic hook section. The elastic hooks are configured to engage in corresponding hook openings on the carrier body (not shown) in order to releasably connect the pivoting device 200 to the latter.

The elastic hook section thus permits a stable and reliable connection of the pivoting device 200 to the carrier body without making it more difficult to remove the pivoting device 200 from the carrier body. The elastic hooks can be easily released during disassembly, as a result of which the pivoting device 200 can be removed again without residues on the carrier body. As a result, components can be replaced simply and quickly, for example, in the event of a fault, as a result of which downtimes and/or maintenance times are reduced.

The fastening of cables 401 to the pivoting device 200 will as well be explained with reference to FIG. 4.

If a cable 401 is to be fastened to the pivoting device 200, it is placed on the concave bearing surface 202. The concave shape of the bearing surface in this case prevents lateral slipping away and permits, in particular, the simultaneous bearing of a plurality of cables, even of different diameters.

In a further step, a fastening means 204, for example a cable tie, is inserted into the holding section 203 from the left-hand side below the concave bearing surface 202 and is guided through said holding section until the fastening means 204 makes contact with the alignment section 206. Said alignment section then ensures, on the one hand, that the fastening means 204 does not remain stuck in the holding section 203 and, on the other hand, the alignment section 206 guides the fastening means 204 back onto the front side of the pivoting device 200. Furthermore, the alignment section 206 is also configured to guide the fastening means such that it can be gripped easily.

In the exemplary embodiment shown, for this purpose, the alignment section 206 has an arc-shaped deflection section at which a fastening means which is guided through the holding section 203 is deflected. In particular, a fastening means 204 which has been guided through parallel to a main direction of extension of the holding section 203 is aligned such that, when it leaves the alignment section 206, it runs in a direction not parallel to the main direction of extension of the holding section 203.

In advantageous configurations, the ends of the alignment section 203 may have angles with respect to one another in the range of 50° to 130°. Further preferably, the ends may have an angle with respect to one another in the range of 70° to 100°.

As a result, depending on the selection of the angle, there is the possibility of aligning different fastening means 204. In this case, the angle is to be selected according to the properties of the fastening means 204 to be aligned. In particular, thickness or rigidity of the fastening means 204 to be deflected may have a great influence on a minimum angle at which a fastening means is still aligned satisfactorily.

For fastening one or more cables 401, the fastening means 204 therefore runs around the concave bearing surface 202 in a circumferential direction, wherein it extends through the rear-side holding section 203 and the alignment section 206. For this purpose, reference is also made to FIG. 8.

In this case, the alignment section 206 advantageously permits fastening means 204 to be used even at locations on the pivoting device 200 which are difficult to access, in order to fasten cables 401 thereto.

Particularly advantageously, fastening means can also be guided through the holding section 203 before the pivoting device 200 is connected to the carrier body. In this way, the later mounting of the electronics housing 100 and of the corresponding cabling can be accelerated further since threading-in and/or guiding-through of fastening means 204 is completely avoided as soon as the pivoting device 200 is no longer easily accessible.

FIG. 5 shows, by way of example and schematically, cables 401 fastened to a pivoting device 200.

The outer side of the pivoting device 200 is shown again. A carrier body is not illustrated.

In the advantageous configuration of FIG. 5, a plurality of cables of thinner cross section are combined to form a thick cable which is fastened to the cable fastening portions 201 of the pivoting device 200. The thick cable may either be embodied in the form of a bundle of individual strands to form a strand or else in the form of a sheathed line in the case of which many individual strands are surrounded by a common sheath.

The splitting into a plurality of cables 401 of smaller cross section is effected here on the sides of the electronics housing 100 (not illustrated). The illustrated plugs on the cables are correspondingly connected to one or more electrical circuit boards (likewise not illustrated).

For this purpose, cable ties are used as fastening means 204. These have the advantage that they can be removed quickly again with destruction of the cable ties, for example in order to correct the cabling or to replace one or more cables 401.

Furthermore, it is shown schematically in FIG. 5 that cables 401 with excess lengths have been prepared and fastened to the pivoting device 200, wherein, in particular, cable excess lengths are located on the electronics housing side of the fastening to the pivoting device 200. In this way, it can be ensured that the electronics housing 100 can be pivoted even when cables 401 are connected, substantially without forces, in particular tensile forces, acting on the cable connections.

As a result, flexible positioning of the electronics housing 100 is possible since, during the positioning, there is no need to take account of any obstructions to view and/or access by the mounted electronics housing 100. If the mounted electronics housing 100 blocks the view on or the access to other assemblies and/or elements, it can be pivoted out of the way. If, in this case, the cables 401 are fastened to the pivoting device 200 correspondingly including the described excess lengths, there is no risk of interrupting a cable connection during the pivoting of the electronics housing 100.

Such a possible pivoting movement is illustrated in FIGS. 6 and 7.

Both figures show the same advantageous embodiment of a housing assembly 300. In this case, the housing assembly 300 comprises a plurality of housing elements which together define an interior space and an electronics housing 100. In this case, an advantageous embodiment of the electronics housing 100 in a closed state is fastened in a pivotable manner by means of the pivoting device 200 to a housing element which thus functions as a carrier body for the electronics housing 100.

In FIG. 6, the electronics housing 100 is shown in a pivoted-out position. This position is, for example, a service position in which the access to the interior space 301 of the housing assembly 300 is released. Access to elements and assemblies in the interior space 301 is not blocked by the electronics housing 100.

If the access is no longer required, the electronics housing 100 can be pivoted in again. This position is illustrated in FIG. 7.

The electronics housing 100 is now located, for example, in an operating position. In this position, the electronics housing 100 is located completely in the interior space 301 of the housing assembly 300. This position of the electronics housing 100 is space-saving, but access to elements and assemblies in the interior space 301 is made more difficult.

In addition to the space saving which results from the pivotability of the electronics housing 100 in the course of the cable fastening with cable excess lengths to the pivoting device 200, the flexibility obtained during the positioning of the electronics housing 100 also permits particular attention to be paid to the electromagnetic compatibility.

The electronics housing 100 can advantageously be accommodated at a location in the interior space 301 of a housing assembly 300 which is as far away as possible from sources of interference, such as motors, pumps and/or power electronic components.

As a result, the electronics housing 100 is particularly suitable for accommodating electronic circuit boards with sensitive electrical components, that is to say, for example, electrical circuit boards with control electronics.

Particularly advantageously, the housing 101 of the electronics housing 100 is shielded for this purpose.

FIG. 8 shows a cross section of an advantageous exemplary embodiment of the pivoting device 200 with cables 401 fastened thereto, perpendicular to a main direction of extension of the cable 401.

As already explained above, a cable 401 can be fastened to the pivoting device 200. For this purpose, the cable 401 to be fastened is first placed on the concave bearing surface 202, or brought into contact with the latter.

In a further step, the fastening means 204 is inserted into the holding section 203, which is located on the rear side of the concave bearing surface 202.

The insertion of the fastening means 204 is effected, in particular, not on that side of the holding section 203 on which the alignment section 206 is located.

If alignment sections 206 are advantageously located at both ends of the holding section 203, each of the alignment sections 206 can be used in order to insert a fastening means into the holding section 203. In particular, an alignment section 206 can be selected in this case depending on the accessibility.

The fastening means 204 is then guided through the holding section 203 until it is guided back through the alignment section 206 onto the front side, or the side of the pivoting device 200, on which the concave bearing surface 202 is located.

Owing to the deflection of the guided-through end of the fastening means 204, it is then easily accessible and can be gripped manually, for example, in order to close the fastening means 204 and thus fasten the cable 401 to the cable fastening portion 201 of the pivoting device 200.

A cable tie as fastening means 204 is illustrated schematically in FIG. 8. It has been tightened in such a way that it presses the cable 401 onto the concave bearing surface 202. The tightening of a cable tie is in particular also facilitated by the alignment section 206, which makes the end of the cable tie which is to be tightened easily accessible and thus also enables simple adjustment of the cable tie position, for example.

Advantageously, a fastening means 204, in particular a cable tie, can also be used in order to fasten a plurality of cables 401 to the pivoting device 200.

If a cable tie is used as fastening means 204, the contact space available on the concave bearing surface 202 is not limiting the number of cables 401 which can be fastened to the corresponding pivoting device. In other words, a cable tie can also be used to fasten more cables 401 to a pivoting device than can simultaneously rest on the concave bearing surface 202.

Furthermore, cables 401 can also be fastened to the pivoting device, the diameter of which is so large that it projects laterally beyond the concave bearing surface 202 in the sectional view.

FIG. 9 shows a cross section of an advantageous exemplary embodiment of the pivoting device with cables fastened thereto, parallel to a main direction of extension of the cable.

In the exemplary embodiment of the pivoting device 200 illustrated in FIG. 9, it can be seen that the fastened cable 401 is fastened only by means of a fastening means 204. For this purpose, the fastening means 204 engages into one of the two illustrated holding sections 203. The profile of the cable 401 is therefore limited only in the upper region of the pivoting device 200, as a result of which the cabling away from the pivoting device is facilitated.

Furthermore, the cable 401 can optionally be removed from the lower concave bearing surface 202 in this way, such that further cables 401 can be placed and fastened there. As a result, more flexible cabling can be achieved without, however, having to dispense with the described advantages of the fastening of cables 401 to the pivoting device 200 of the electronics housing 100.

If particularly safe fixing to the pivoting device 200 is required for a cable 401, for example on account of a large diameter or the bundle of many different cables 401, the cable 401 can also be fastened to the pivoting device by means of a plurality of fastening means 204. In this case, the fastening means 204 can in particular in each case engage into different holding sections 203. If the fastening means 204 are selected with corresponding dimensions, two or more fastening means 204 can also engage into the same holding section 203 in order to fasten a cable 401 to the pivoting device 200.

Exemplary embodiments of the present invention and the advantages thereof have been described in detail above with reference to the appended figures.

It is once again emphasized that the present invention is in no way limited to the exemplary embodiments described above and the exemplary features thereof. The invention furthermore comprises modifications of the exemplary embodiments mentioned, in particular those which emerge from modifications and/or combinations of individual or a plurality of features of the exemplary embodiments described within the scope of the independent claims.

### LIST OF REFERENCE SIGNS

100 electronics housing
101 housing of the electronics housing
102 accommodation space
200 pivoting device
201 cable fastening portion
202 concave bearing surface
203 holding section
204 fastening means
205 attachment interface section
206 alignment section
207 connecting means
208 positioning aid
300 housing assembly
301 interior space
302 housing element
400 electrical circuit board
401 cable

1. A pivotable electronics housing (100) for accommodating electrical circuit boards (400), comprising
a housing (101) which surrounds an accommodation space (102) in which at least one electrical circuit board (400) can be accommodated; and
at least one pivoting device (200) for fastening the housing (101) to a carrier body;
wherein
the at least one pivoting device (200), in a state in which it is fastened to the carrier body, permits at least one pivoting movement of the housing (101) relative to the carrier body;
the at least one pivoting device (200) is a cable-guiding pivoting device (200) which is designed to guide a portion of a cable (401) which runs from a surrounding area of the housing (101) into the accommodation space (102); and
the cable-guiding pivoting device (200) comprises at least one cable fastening portion (201) which has a concave bearing surface (202), on which the portion of the cable (401) can rest, and a holding section (203) which is located below the bearing surface (202) and on which a fastening means (204) can engage in order to fasten the portion of the cable (401), which rests on the bearing surface (202), to the pivoting device (200).

2. The electronics housing (100) according to claim 1, wherein the pivoting device (200) comprises an attachment interface section (205) which is adapted to a receiving section of the carrier body in such a way that the pivoting device (200) is fastened to the carrier body in a form-fitting and/or force-fitting manner when the attachment interface section (205) and the receiving section are brought into interaction, wherein the attachment interface section (205) and the receiving section can preferably be released from one another in a non-destructive manner.

3. The electronics housing according to claim 2, wherein the attachment interface section (205) and the receiving section are configured in such a way that they can be released from one another by elastic deformation of the attachment interface section (205) and/or of the receiving section.

4. The electronics housing (100) according to claim 3, wherein the attachment interface section (205) and the receiving section are designed as a latching mechanism in which an elastic latching or hook section (205) engages in a latching or hook opening adapted thereto when the attachment interface section (205) and the receiving section are brought into interaction.

5. The electronics housing (100) according to claim 1, wherein the at least one cable fastening portion (201) has an alignment section (206) for guiding and/or aligning the fastening means (204), which alignment section guides the fastening means (204) during a movement of the fastening means relative to the holding section (203) and/or aligns it with respect to the holding section (203) when the fastening means is brought into interaction with the alignment section (206).

6. The electronics housing (100) according to one claim 1, wherein the holding section (203) is of groove-shaped design and the alignment section (206) is preferably formed by an arc-shaped deflection section, at which a fastening means (204), which is guided relative to the holding section (203), is deflected in the direction of the bearing surface, preferably ends of the deflection section are at an angle of 50° to 130° with respect to one another, particularly preferably at an angle of 70° to 100°.

7. The electronics housing (100) according to one claim 1, wherein the pivoting device (200) is of multi-part design and comprises at least one carrier-body-side part and one housing-side part which can be pivoted with respect to one another and which are releasably connected to one another via a connecting means (207), wherein preferably the carrier-body-side part has the at least one cable fastening portion (201).

8. Electronics The electronics housing (100) according to one claim 1, wherein the pivoting device (200) additionally comprises a positioning aid (208) by means of which the pivoting device (200) can be positioned in a connecting position on and/or in the carrier body.

9. The electronics housing (100) according to one claim 1, wherein the pivoting device (200) comprises one or more further cable fastening portions (201) which each have a concave bearing surface (202), on which the portion of the cable (401) can rest, and a holding section (203) which is located below the bearing surface (202) and on which a fastening means (204) can engage in order to fasten the portion of the cable (401), which rests on the bearing surface (202), to the pivoting device (200).

10. The electronics housing (100) according to Claim 9, wherein the at least one cable fastening portion (201) and the one or more further cable fastening portions (201) are arranged symmetrically.

11. The electronics housing (100) according to claim 1, wherein the electronics housing (100) comprises one or more further pivoting devices (200).

12. A pivoting device of an electronics housing (100) according to one claim 1.

13. A pivotable electronics device, comprising:
a pivotable electronics housing (100) according to claim 1; and
at least one electrical circuit board (400) which is accommodated in the accommodation space (102) of the electronics housing (100).

14. A housing assembly (300) for use in a climate control unit, comprising:
one or more housing elements (302) which together define an interior space, and
an electronics housing (100) according to claim 1;
wherein the electronics housing (100), by way of its pivoting device (200), is fastened in a pivotable manner to one of the one or more housing elements (302) which functions as a carrier body for the electronics housing, preferably in such a way that the electronics housing (100), at least in a first pivoting position of the electronics housing (100), lies partially or completely in the interior space.

15. A climate control unit, comprising:
a housing assembly (300) according to claim 13;
at least one electrical circuit board (400) which is accommodated in the accommodation space (102) of the electronics housing (100); and
at least one cable (401) which is connected to the at least one circuit board (400) and is guided out of the accommodation space (102) by way of the cable-guiding pivoting device (200);
wherein the at least one cable (401) rests on the bearing surface (202) and is fastened to the pivoting device (200) by means of a fastening means (204) which engages on the holding section (203).
